(19) United States
(12) Patent Application Publication
(10) Pub. No.: US 2021/0231294 A1
(43) Pub. Date: Jul. 29, 2021

(54) WAVELENGTH CONVERSION MEMBER AND WAVELENGTH CONVERSION ELEMENT, METHOD FOR MANUFACTURING SAME, AND LIGHT-EMITTING DEVICE

(71) Applicant: NIPPON ELECTRIC GLASS CO., LTD., Otsu-shi, Shiga (JP)

(72) Inventors: Shotaro FUKUMOTO, Otsu-shi (JP); Tadahito FURUYAMA, Otsu-shi (JP); Shunsuke FUJITA, Otsu-shi (JP)

(21) Appl. No.: 17/052,822

(22) PCT Filed: May 24, 2019
(86) PCT No.: PCT/JP2019/020654

§ 371 Date: Nov. 4, 2020

(30) Foreign Application Priority Data
Jun. 12, 2018 (JP) 2018-111613
Oct. 2, 2018 (JP) 2018-187460
Dec. 11, 2018 (JP) 2018-231686
Mar. 26, 2019 (JP) 2019-057862

(51) Int. Cl. F21V 9/32; C09K 11/02; C09K 11/77

(52) U.S. Cl. CPC F21V 9/32; F21Y 2115/30; C09K 11/7706; C09K 11/02

(57) ABSTRACT

The present invention has an object of providing: a wavelength conversion member and a wavelength conversion element which are capable of reducing the decrease in luminescence intensity with time and the melting of component materials when irradiated with high-power LED or LD light; manufacturing methods of the wavelength conversion member and the wavelength conversion element; and a light-emitting device. A wavelength conversion member 10 containing a matrix 1 and phosphor particles 2 dispersed in the matrix 1, the matrix 1 comprising: a skeleton made of an inorganic material 3; and a transparent material 4 filled in a hole formed by the skeleton, the inorganic material 3 having a higher thermal conductivity than the transparent material 4.

### TECHNICAL FIELD

The present invention relates to wavelength conversion members and wavelength conversion elements for converting the wavelength of light emitted from light emitting diodes (LEDs), laser diodes (LDs) or the like to another wavelength, methods for manufacturing the wavelength conversion members, methods for manufacturing the wavelength conversion elements, and light-emitting devices.

### BACKGROUND ART

Recently, attention has been increasingly focused on light-emitting devices using LEDs or LDs as next-generation light-emitting devices to replace fluorescence lamps and incandescent lamps, from the viewpoint of their low power consumption, small size, light weight, and easy adjustment to light intensity. For example, Patent Literature 1 discloses, as an example of such a next-generation light-emitting device, a light-emitting device in which a wavelength conversion member is disposed on an LED capable of emitting a blue light and absorbs part of the light from the LED to convert it to a yellow light. This light-emitting device emits a white light which is a synthetic light of the blue light emitted from the LED and the yellow light emitted from the wavelength conversion member.

As a wavelength conversion member, there has conventionally been used a wavelength conversion member in which phosphor particles are dispersed in a resin matrix. However, in such a wavelength conversion member using a resin matrix, the resin matrix may be discolored or deformed by the application of heat or irradiation light emitted from an LED or an LD, which causes performance degradation of the wavelength conversion member.

To cope with the above, a wavelength conversion member is recently being proposed which is formed of a fully inorganic solid in which phosphor particles are dispersed and set in, instead of the resin, a glass matrix (see, for example, Patent Literatures 2 and 3). This wavelength conversion member has the feature that the glass matrix constituting a base material is less likely to be degraded by heat and irradiation light from the LED and therefore less likely to cause problems of discoloration and deformation.

### CITATION LIST

### Patent Literature

### [PTL 1]

JP-A-2000-208815

### [PTL 2]

JP-A-2003-258308

### [PTL 3]

JP-B2-4895541

### SUMMARY OF INVENTION

### Technical Problem

Recently, the power of an LED or an LD for use as a light source is increasing for the purpose of providing higher power to a light-emitting device. Along with this, the intensity of heat from the light source and heat emitted by the phosphor particles irradiated with excitation light increases, so that the temperature rise of the wavelength conversion member is becoming significant. As a result, there arise a problem that the luminescence intensity decreases with time (temperature quenching) and a problem that in some cases the matrix material melts.

In view of the foregoing, the present invention has an object of providing: a wavelength conversion member and a wavelength conversion element which are capable of reducing the decrease in luminescence intensity with time and the melting of component materials when irradiated with high-power LED or LD light; manufacturing methods of the wavelength conversion member and the wavelength conversion element; and a light-emitting device.

### Solution to Problem

A wavelength conversion member according to the present invention is a wavelength conversion member containing a matrix and phosphor particles dispersed in the matrix, wherein the matrix comprises: a skeleton made of an inorganic material; and a transparent material filled in a hole formed by the skeleton, and the inorganic material has a higher thermal conductivity than the transparent material.

In the above structure, the skeleton made of an inorganic material has a higher thermal conductivity than glass and resin and serves as a heat conduction path to efficiently release heat from the light source and heat emitted by the phosphor particles upon application of excitation light to the wavelength conversion member, so that the temperature rise of the wavelength conversion member can be reduced. Furthermore, since a transparent material is filled in the hole formed by the skeleton made of an inorganic material, the refractive index difference between the skeleton and the hole can be reduced, so that light scattering can be reduced. As a result, the light permeability of the wavelength conversion member increases, so that excitation light and fluorescence emitted from the phosphor particles can be efficiently extracted.

In the wavelength conversion member according to the present invention, the skeleton is preferably formed of a sintered body. By doing so, the thermal conductivity of the skeleton can be easily increased.

In the wavelength conversion member according to the present invention, the phosphor particles are preferably dispersed in the hole.

In the wavelength conversion member according to the present invention, the phosphor particles are preferably dispersed inside of the skeleton.

In the wavelength conversion member according to the present invention, the phosphor particles preferably adjoin both the skeleton and the hole.

In the wavelength conversion member according to the present invention, a volume proportion of the transparent material in the entire wavelength conversion member is preferably 10 to 80%. Thus, the light permeability and the heat dissipation can be balanced.

In the wavelength conversion member according to the present invention, difference in a refractive index between the inorganic material and the transparent material is preferably 0.3 or less. Thus, excessive scattering occurring at the interface between the skeleton made of the inorganic material and the transparent material can be reduced and the scattering state can be controlled to efficiently extract fluorescence emitted from the phosphor particles.

In the wavelength conversion member according to the present invention, the skeleton is preferably formed by three-dimensional continuation of powder of the inorganic material.

In the wavelength conversion member according to the present invention, the hole is preferably substantially free from discreteness. By doing so, the transparent material can be sufficiently filled in and surplus scattering can be reduced.

In the wavelength conversion member according to the present invention, the inorganic material preferably contains at least one selected from among aluminum oxide, magnesium oxide, zinc oxide, aluminum nitride, and boron nitride. The above inorganic materials have high thermal conductivity as compared to the transparent material, such as glass or resin. Therefore, the skeleton made of such an inorganic material has a high thermal conductivity and, thus, can effectively release heat emitted by the phosphor particles to the outside.

In the wavelength conversion member according to the present invention, the transparent material is preferably glass.

In the wavelength conversion member according to the present invention, the transparent material is preferably resin.

The wavelength conversion member according to the present invention preferably has a thickness of 1000 μm or less. Thus, excessive scattering of the wavelength conversion member can be reduced, so that its luminous efficiency can be increased.

The wavelength conversion member according to the present invention preferably has a thermal diffusivity of 1×10⁻⁶ m²/s or more. Thus, excessive heat generation of the wavelength conversion member can be reduced, so that its luminous efficiency can be increased.

The wavelength conversion member according to the present invention preferably has a quantum efficiency of 20% or more.

A method for manufacturing a wavelength conversion member according to the present invention is a method for manufacturing the above-described wavelength conversion member and comprises the steps of: firing powder of an inorganic material to make a skeleton made of the inorganic material; preparing a mixture of phosphor particles and a transparent material; and impregnating a hole formed by the skeleton with the mixture.

In the method for manufacturing the wavelength conversion member according to the present invention, a maximum temperature during the firing of the powder of the inorganic material is preferably 1600° C. or lower.

In the method for manufacturing the wavelength conversion member according to the present invention, a maximum temperature during the impregnation of the skeleton with the mixture of the phosphor particles and the transparent material is 1000° C. or lower.

A method for manufacturing a wavelength conversion member according to the present invention is a method for manufacturing the above-described wavelength conversion member and comprises the steps of: preparing a mixture of phosphor particles and powder of an inorganic material; firing the mixture to produce a sintered body having a skeleton made of the inorganic material and containing the phosphor particles dispersed inside of the skeleton; and impregnating a hole formed by the skeleton with a transparent material.

In the method for manufacturing the wavelength conversion member according to the present invention, a maximum temperature during the firing of the mixture of the phosphor particles and the powder of the inorganic material is preferably 1600° C. or lower.

In the method for manufacturing the wavelength conversion member according to the present invention, a maximum temperature during the impregnation of the skeleton with the transparent material is 1000° C. or lower.

In the method for manufacturing the wavelength conversion member according to the present invention, the powder of the inorganic material preferably has an average particle diameter of 3 μm or more.

A wavelength conversion element according to the present invention includes: the above-described wavelength conversion member; and a substrate joined to the wavelength conversion member.

In the wavelength conversion element according to the present invention, the substrate is preferably joined to the wavelength conversion member with the transparent material exposed on a surface of the wavelength conversion member.

A method for manufacturing a wavelength conversion element according to the present invention includes the steps of: firing powder of an inorganic material to make a skeleton made of the inorganic material; preparing a mixture of phosphor particles and a transparent material; impregnating a hole formed by the skeleton with the mixture; and bringing a substrate and the skeleton into tight contact with each other before the mixture hardens and joining the skeleton and the substrate together with the mixture exposed from the hole.

A method for manufacturing a wavelength conversion element according to the present invention includes the steps of: preparing a mixture of phosphor particles and powder of an inorganic material; firing the mixture to produce a sintered body having a skeleton made of the inorganic material and containing the phosphor particles dispersed inside of the skeleton; impregnating a hole formed by the skeleton with a transparent material; and bringing a substrate and the sintered body into tight contact with each other before the transparent material hardens and joining the sintered body and the substrate together with the transparent material exposed from the hole.

A light-emitting device according to the present invention includes: the above-described wavelength conversion member; and a light source operable to irradiate the wavelength conversion member with excitation light.

A light-emitting device according to the present invention includes: the above-described wavelength conversion element; and a light source operable to irradiate the wavelength conversion element with excitation light.

In the light-emitting device according to the present invention, the light source is preferably a laser diode.

### Advantageous Effects of Invention

The present invention enables provision of: a wavelength conversion member and a wavelength conversion element which are capable of reducing the decrease in luminescence intensity with time and the melting of component materials when irradiated with high-power LED or LD light; manufacturing methods of the wavelength conversion member and the wavelength conversion element; and a light-emitting device.

### BRIEF DESCRIPTION OF DRAWINGS

FIG. 1 is a schematic cross-sectional view showing one embodiment of a wavelength conversion member according to the present invention.

FIG. 2 is a photograph of a partial cross section of a wavelength conversion member in Example 1.

FIG. 3 is a schematic cross-sectional view showing one embodiment of a wavelength conversion element according to the present invention.

FIG. 4 is a schematic cross-sectional view showing a light-emitting device in which the wavelength conversion member according to the one embodiment of the present invention is used.

FIG. 5 is a schematic cross-sectional view showing a light-emitting device in which the wavelength conversion element according to the one embodiment of the present invention is used.

### DESCRIPTION OF EMBODIMENTS

Hereinafter, an embodiment of the present invention will be described in detail with reference to the drawings. However, the present invention is not at all limited to the following embodiment.

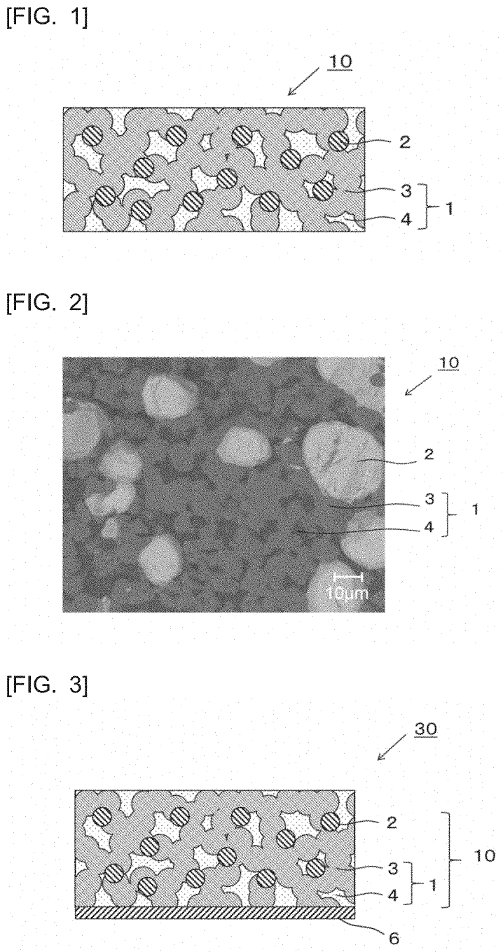

FIG. 1 is a schematic cross-sectional view showing a wavelength conversion member according to one embodiment of the present invention. The wavelength conversion member 10 contains phosphor particles 2 inside of a matrix 1. The matrix 1 is formed of: a skeleton made of an inorganic material 3; and a transparent material 4 filled in a hole in the skeleton made of the inorganic material 3. The phosphor particles 2 are dispersed, in contact with either one or both of the inorganic material 3 and the transparent material 4, inside of the matrix 1. The entire hole is preferably filled with the transparent material 4, but part of the hole may not be filled with the transparent material 4. Hereinafter, a detailed description will be given of the components.

(Phosphor Particles)

There is no particular limitation as to the type of phosphor particles in the present invention so long as they can emit fluorescence upon incidence of excitation light, but specific examples include oxide phosphor, nitride phosphor, oxynitride phosphor, chloride phosphor, oxychloride phosphor, sulfide phosphor, oxysulfide phosphor, halide phosphor, chalcogenide phosphor, aluminate phosphor, and halophosphoric acid chloride phosphor. These types of phosphors may be used singly or in a mixture of two or more of them.

As will be described later, examples of a method for obtaining a wavelength conversion member in which phosphor particles are dispersed in a matrix include a manufacturing method (i) including the steps of: firing powder of an inorganic material to make a skeleton made of the inorganic material; preparing a mixture of phosphor particles and a transparent material; and impregnating a hole formed by the skeleton with the mixture, and a manufacturing method (ii) including the steps of: preparing a mixture of phosphor particles and powder of an inorganic material; firing the mixture to produce a sintered body having a skeleton made of the inorganic material and containing the phosphor particles dispersed inside of the skeleton; and impregnating a hole formed by the skeleton with a transparent material. Particularly in the case of obtaining a wavelength conversion member by the manufacturing method (ii) or the case of using glass as the transparent material, the phosphor particles for use are preferably those less likely to cause thermal degradation during the firing or the impregnation. From the above perspective, phosphor particles are preferably particles of an oxide phosphor and particularly preferably particles of an oxide phosphor having a garnet structure (such as Y₃Al₅O₁₂:Ce³⁺ or Lu₃Al₅O₁₂:Ce³⁺).

The average particle diameter (D₅₀) of the phosphor particles is preferably 1 to 50 μm, more preferably 3 to 30 μm, and particularly preferably 5 to 30 μm. If the average particle diameter of the phosphor particles is too small, the luminescence intensity is likely to decrease. On the other hand, if the average particle diameter thereof is too large, it is difficult to uniformly disperse the phosphor particles into the matrix, so that the luminescent color may be heterogeneous. The average particle diameter used in the present invention means a value measured by laser diffractometry and indicates the particle diameter when in a volume-based cumulative particle size distribution curve as determined by laser diffractometry the integrated value of cumulative volume from the smaller particle diameter is 50%.

The percentage by volume of the phosphor particles in the total amount of the phosphor particles and the inorganic material is, in both the above-described methods (i) and (ii), preferably 0.01 to 90%, more preferably 0.01 to 70%, and particularly preferably 0.01 to 50%. Hereinafter, the percentage by volume of phosphor particles in the total amount of the phosphor particles and an inorganic material will be described as the content of phosphor particles. If the content of phosphor particles is too large, the content of inorganic material in a mixture of the phosphor particles and the inorganic material becomes relatively small, so that the thermal conductivity of the matrix may decrease. On the other hand, if the content of phosphor particles is too small, a sufficient luminescence intensity is difficult to obtain. In a transmissive wavelength conversion member described later, if the content of phosphor particles is too high, the amount of transmitted excitation light becomes small due to light absorption of the phosphor particles, so that the chromaticity of the transmitted light is likely to shift to that of fluorescence. As a result, the chromaticity control of the emitted light may be difficult. Therefore, the content of phosphor particles is preferably low. Specifically, in a transmissive wavelength conversion member, the content of phosphor particles is preferably 0.01 to 50%, more preferably 0.1 to 35%, and particularly preferably 1 to 20%.

The phosphor particles can be given the effects of the present invention so long as they are dispersed in the matrix. Specific examples of the dispersed state of phosphor particles include: a state (1) of dispersion in the hole; and a state (2) of dispersion inside of the skeleton. The state (1) is preferred because it can be relatively easily produced by the above-described manufacturing method (i). The state (2) can be produced by the above-described manufacturing method (ii) and is preferred because a highly thermally conductive skeleton and phosphor particles bind together and, therefore, heat emitted by the phosphor particles can be particularly effectively released to the outside. The phosphor particles may adjoin both the skeleton and the hole.

(Matrix)

(Inorganic Material)

The inorganic material is preferably ceramic powder. Specifically, the inorganic material preferably contains at least one selected from among aluminum oxide, magnesium oxide, zinc oxide, aluminum nitride, and boron nitride. Alternatively, as will be described later, examples of the powder of inorganic material that can be used as a raw material include, apart from the above inorganic materials, raw materials that can provide at least one selected from among aluminum oxide, magnesium oxide, zinc oxide, aluminum nitride, and boron nitride when fired. For example, hydroxides, carbonates, fluorides, and chlorides can be used. These types of materials may be used singly or in a mixture of two or more of them. The above inorganic materials have high thermal conductivity as compared to the transparent material, such as glass or resin, and therefore can effectively release heat emitted by the phosphor particles to the outside. Among them, aluminum oxide and magnesium oxide are preferred because they have relatively high thermal conductivity. Particularly, magnesium oxide is more preferred because it has not only a high thermal conductivity but also less light absorption.

The inorganic material has a higher thermal conductivity than the transparent material. Specifically, the thermal conductivity of the inorganic material is preferably 5 W·m⁻¹·K⁻¹ or more, more preferably 10 W·m⁻¹·K⁻¹ or more, and particularly preferably 25 W·m⁻¹·K⁻¹ or more. Thus, heat emitted by the phosphor particles can be more effectively released to the outside. The thermal conductivity of magnesium oxide is about 45 to 60 W·m⁻¹·K⁻¹.

The skeleton made of an inorganic material is preferably formed by three-dimensional continuation of powder of the inorganic material and, particularly preferably, the powder of the inorganic material forms a bicontinuous porous body (a porous body in which a skeleton and a hole are three-dimensionally continuous to each other). With this structure, the transparent material can be more easily impregnated into the inside of the matrix. In addition, heat emitted by the phosphor particles can be more effectively released to the outside. In the present invention, the three-dimensional continuation of the inorganic material powder can be confirmed from a three-dimensional image taken with a microfocus X-ray CT scanner.

The skeleton made of an inorganic material is preferably formed of a sintered body (sintered powder body). Thus, powder particles of the inorganic material can be easily and sufficiently bound together, so that the thermal conductivity of the skeleton can be easily increased. In the case where a mixture of phosphor particles and powder of an inorganic material is fired in the below-described manufacturing method, a sintered mixture body can be obtained in which the phosphor particles are dispersed inside of a skeleton made of the inorganic material. When such a sintered mixture body is impregnated with a transparent material, a wavelength conversion member can be obtained in which a skeleton made of the inorganic material is a sintered body and the phosphor particles are dispersed inside of the skeleton or adjoin both the skeleton and the hole. The sintered mixture body is preferred because the phosphor particles and the skeleton are bound to each other by firing and, therefore, heat emitted by the phosphor particles can be more effectively released to the outside.

The hole formed by the skeleton is preferably substantially free from discreteness. Thus, the hole can be sufficiently filled with the transparent material, so that surplus scattering can be reduced. The term “substantially free from discreteness” in the present invention refers to the case where, in a three-dimensional image of a skeleton taken with a microfocus X-ray CT scanner, the proportion of the volume of discrete hole portions to the volume of the entire hole is 1% or less.

The central pore diameter of the hole is preferably 0.05 μm to 50 μm, more preferably 0.1 μm to 40 μm, and particularly preferably 0.5 μm to 30 μm. If the central pore diameter is too small, the hole is not sufficiently filled with the transparent material and voids remain in the hole, which causes excessive scattering. On the other hand, if the pore diameter is too large, even if the phosphor particles are dispersed in the hole, the phosphor particles are not sufficiently in contact with the skeleton made of an inorganic substance, so that heat emitted from the phosphor particles cannot sufficiently be released. The central pore diameter in the present invention means a value measured by mercury porosimetry and indicates a pore diameter corresponding to a larger peak value in a pore diameter distribution measured by the mercury porosimetry.

(Transparent Material)

Glass or resin can be used as the transparent material. Considering thermal degradation of the phosphor particles, the softening point of the glass for use as the transparent material is preferably 250 to 1000° C., more preferably 300 to 950° C., and particularly preferably 350 to 900° C. Glass has good thermal resistance as compared to resin which is an organic matrix. Therefore, a wavelength conversion member having more excellent thermal resistance can be produced. If the softening point of the glass is too low, the glass may be softened and deformed by heat produced by the phosphor particles. On the other hand, if the softening point of the glass is too high, it is necessary to perform the impregnation treatment at a higher temperature. Therefore, in the case of using phosphor particles having low thermal resistance, the softening point of the glass is preferably not higher than 600° C.

Examples of resin for use as the transparent material include common resins, including thermoplastic resin, such as silicone, and thermosetting resin, such as epoxy resin. Resin has a low softening point as compared to glass and, therefore, can be used in the impregnation treatment at a lower temperature. Therefore, resin is useful particularly when used together with phosphor particles having low thermal resistance, which results in a reduction of the production cost. In addition, resin has a small specific gravity as compared to glass, so that a lighter wavelength conversion member can be produced.

As thus far described, an optimum transparent material can be used in consideration of the thermal resistance of the phosphor particles and the production cost.

The volume proportion of the transparent material in the entire wavelength conversion member is preferably 10 to 80%, more preferably 20 to 60%, and particularly preferably 30 to 50%. If the proportion of the transparent material is too large, the amount of inorganic material forming the skeleton becomes excessively small, so that a desired heat dissipation effect is difficult to achieve. On the other hand, if the proportion of the transparent material is too small, the volume of hole not filled with the transparent material increases and the air remains inside of the hole. As a result, it is difficult to reduce light scattering due to a difference in refractive index (nd) between the air and the matrix, so that the light permeability of the wavelength conversion member decreases and, therefore, the light extraction efficiency decreases.

The difference in refractive index (nd) between the inorganic material constituting the matrix and the transparent material is preferably 0.3 or less, more preferably 0.2 or less, and particularly preferably 0.1 or less. Thus, excessive scattering occurring at the interface between the skeleton made of the inorganic material and the transparent material can be reduced, so that the scattering state can be controlled to efficiently extract fluorescence emitted from the phosphor particles. However, the difference in refractive index is not limited to the above.

(Wavelength Conversion Member)

There is no particular limitation as to the shape of the wavelength conversion member, but the shape is generally a sheet-like shape (such as a rectangular sheet-like shape or a disc-like shape). The thickness of the wavelength conversion member can be appropriately selected to obtain light having a desired color, but, specifically, is preferably 1000 μm or less, more preferably 800 μm or less, and particularly preferably 500 μm or less. If the thickness of the wavelength conversion member is too large, scattering and absorption of light in the wavelength conversion member become too much, so that the efficiency of emission of excitation light and fluorescence tends to decrease. The thickness of the wavelength conversion member is preferably not less than 30 μm, more preferably not less than 50 μm, and particularly preferably not less than 80 μm. If the thickness of the wavelength conversion member is too small, its mechanical strength is likely to decrease. In addition, because the content of the phosphor particles needs to be increased in order to obtain a desired luminescence intensity, the amount of the skeleton made of an inorganic material and the amount of the transparent material are relatively reduced, so that the thermal conductivity and the light transmission properties tend to decrease.

As thus far described, since the wavelength conversion member according to the present invention comprises phosphor particles and a matrix having excellent thermal conductivity, it is likely to have a high thermal diffusivity. Specifically, the thermal diffusivity of the wavelength conversion member is preferably 1×10⁻⁶ m²/s or more, more preferably 1.5×10⁻⁶ m²/s or more, and particularly preferably 2×10⁻⁶ m²/s or more.

The quantum efficiency of the wavelength conversion member is preferably 20% or more, more preferably 30% or more, still more preferably 50% or more, and particularly preferably 60% or more. If the quantum efficiency is too low, the amount of energy lost to heat in light absorbed during wavelength conversion becomes large, so that the temperature of the phosphor is likely to increase. As a result, a luminance reduction is likely to occur due to temperature quenching. In the present invention, the quantum efficiency indicates a value calculated by the following equation and can be measured with an absolute PL quantum yield spectrometer.

Quantum efficiency=[(the number of photons emitted as fluorescence from a sample)/(the number of photons absorbed by the sample)]×100(%)

(Manufacturing Method of Wavelength Conversion Member)

The wavelength conversion member can be manufactured by either one of a manufacturing method (i) including the steps of: firing powder of an inorganic material to make a skeleton made of the inorganic material; preparing a mixture of phosphor particles and a transparent material; and impregnating a hole formed by the skeleton with the mixture, and a manufacturing method (ii) including the steps of: preparing a mixture of phosphor particles and powder of an inorganic material; firing the mixture to produce a sintered body having a skeleton made of the inorganic material and containing the phosphor particles dispersed inside of the skeleton; and impregnating a hole formed by the skeleton with a transparent material.

First, a description will be given of the manufacturing method (i).

First, powder of an inorganic material is pressed by a mold assembly and the obtained preform is fired to produce a sintered body having a skeleton made of the inorganic material. Alternatively, a sintered body can be obtained by adding organic components, including a binder and a solvent, to powder of an inorganic material to form a paste and firing the paste. In this way, a preform having a desired shape can be easily formed using a green sheet forming method or like methods. In doing so, after the organic components are removed from the paste in a degreasing process (at about 600° C.), the paste can be fired at the sintering temperature for the inorganic material powder. Furthermore, after the primary firing, the preform may be subjected to HIP (hot isostatic pressing) at the firing temperature plus/minus 150° C.

Examples of the binder that can be used include polypropylene carbonate, polybutyl methacrylate, polyvinyl butyral, polymethyl methacrylate, polyethyl methacrylate, ethyl cellulose, nitrocellulose, and polyester carbonate and these binders can be used singly or in a mixture.

Examples of the solvent that can be used include terpineol, isoamyl acetate, toluene, methyl ethyl ketone, diethylene glycol monobutyl ether acetate, and 2,2,4-trimethyl-1,3,-pentanediol monoisobutyrate and these solvents can be used singly or in a mixture.

A sintering aid may be contained in the paste. By the addition of the sintering aid, melting between the particles is promoted, so that the thermal conductivity of the skeleton made of an inorganic material can be easily increased. In addition, the firing temperature can be decreased, so that thermal degradation of the phosphor can be easily reduced. Examples of the sintering aid that can be used include crystalline powders of magnesium phosphate, zirconium phosphate, manganese oxide, barium oxide, yttrium oxide, aluminum oxide, silicon oxide, calcium fluoride, magnesium fluoride, and barium fluoride, and amorphous powders of silicate-based oxides and phosphate-based oxides. Particularly, a sintering aid containing the same metal cations as those contained in the inorganic material powder is preferably used. For example, in making a skeleton made of magnesium oxide, magnesium phosphate and/or magnesium fluoride is preferably used as the sintering aid. By doing so, a principal component forming the skeleton made of an inorganic material can be magnesium oxide, so that unintended crystal formation of heterogeneous cations can be easily reduced.

The average particle diameter (D₅₀) of the sintering aid is preferably 10 μm or less, more preferably 7 μm or less, and particularly preferably 5 μm or less. Thus, the sintering aid can easily enter between powder particles of the inorganic material. In addition, the sintering aid has high reactivity and easily softens at lower temperatures, so that the inorganic material powder can be easily melt-bonded together by sintering. As a result, the thermal diffusivity of the wavelength conversion member can be easily increased. If the particle diameter of the sintering aid is too large, the above effects are difficult to achieve. The lower limit of the average particle diameter is not particularly limited, but is generally not less than 0.001 μm.

The mixture of powder of an inorganic material and a sintering aid contains, in terms of % by volume, preferably 0.01 to 30% sintering aid, more preferably 0.1 to 20% sintering aid, and particularly preferably 0.5 to 10% sintering aid. If the sintering aid is too much, the mechanical strength of the skeleton is likely to decrease. If the sintering aid is too less, sintering is difficult to achieve, so that the mechanical strength of the skeleton is likely to decrease. In the case of using the same raw material for powder of an inorganic material and a sintering aid, raw material powder having a smaller particle diameter can be considered to be the sintering aid. In this case, raw material powder having a smaller particle diameter has higher reactivity and is likely to soften at a lower temperature, the reason for which it functions as a sintering aid.

As the inorganic material powder, a raw material may be used which can provide at least one selected from among aluminum oxide, magnesium oxide, zinc oxide, aluminum nitride, and boron nitride when fired. Examples of the raw material that can be used include oxides, nitrides, hydroxides, fluorides, chlorides, and carbonates and, specifically, aluminum oxide, magnesium oxide, zinc oxide, aluminum nitride, boron nitride, magnesium hydroxide, aluminum hydroxide, boron fluoride, magnesium fluoride, aluminum fluoride, magnesium chloride, aluminum chloride, magnesium carbonate, and so on are preferably used. These materials can be used singly or in a mixture. Particularly, magnesium fluoride (MgF₂) is preferably used. Magnesium fluoride can easily sinter at low temperatures. Particularly in the manufacturing method (ii) described later, magnesium fluoride can reduce thermal degradation of phosphor particles due to sintering and thus reduce the decrease in luminous efficiency of the wavelength conversion member. In this case, at least part of the fluorine component (F₂) of magnesium fluoride is eliminated by sintering, so that a skeleton containing magnesium oxide (MgO) can be obtained.

The maximum temperature during firing of the inorganic material powder is preferably 1600° C. or lower, more preferably 1400° C. or lower, and particularly preferably 1200° C. or lower. If the firing temperature is too low, melt bonding between powder particles of the inorganic material becomes insufficient, so that the mechanical strength of the skeleton is likely to decrease. Therefore, the lower limit of the firing temperature is preferably not lower than 700° C., more preferably not lower than 800° C., and particularly preferably not lower than 900° C.

The average particle diameter (D₅₀) of the inorganic material powder is preferably 3 μm to 50 μm, more preferably 3 μm to 30 μm, and particularly preferably 3 μm to 10 μm. If the particle diameter of the inorganic material powder is too small, a hole cannot sufficiently be formed, which makes it difficult to impregnate a matrix with a transparent material. On the other hand, if the particle diameter of the inorganic material powder is too large, particles are less likely to be melt-bonded, which makes it difficult to form a three-dimensionally continuous skeleton.

Next, a mixture of phosphor particles and a transparent material is prepared. The mixing method is not particularly limited, but, for example, a mixture can be prepared by introducing phosphor particles into a liquid resin as a main liquid and a liquid hardener at room temperature. Alternatively, a mixture can be prepared by adding phosphor particles into a glass melted by the application of heat.

When the mixture is introduced into the sintered body, a hole formed by the skeleton made of the inorganic material is impregnated with the transparent material containing the phosphor particles dispersed therein. The temperature for impregnation is preferably 1000° C. or lower, more preferably 950° C. or lower, and particularly preferably 900° C. or lower. If the temperature for impregnation is too high, the phosphor particles are likely to thermally degrade. Furthermore, with the use of a glass as the transparent material, if the temperature for impregnation is too low, softening and flow of the glass become insufficient, so that the glass may not sufficiently be filled in the hole. Therefore, the lower limit of the temperature for impregnation is preferably not lower than 200° C., more preferably not lower than 300° C., and particularly preferably not lower than 400° C. With the use of a resin as the transparent material, the temperature for impregnation with an uncured resin is preferably 100° C. or lower, more preferably 50° C. or lower, and particularly preferably ordinary temperature. Furthermore, with the use of a thermosetting resin, it is preferred to impregnate the sintered body with the resin and then cure the resin by the application of heat. The heating temperature is preferably 350° C. or lower, more preferably 250° C. or lower, and particularly preferably 150° C. or lower. If the heating temperature is too high, the resin may be thermally decomposed. In the wavelength conversion member manufactured by this manufacturing method, the phosphor particles are present in the hole of the skeleton by being dispersed in the transparent material. In this state, the phosphor particles may be in contact with the skeleton. In other words, the phosphor particles may adjoin both the skeleton and the hole.

A description will be given next of the manufacturing method (ii). In this method, a mixture of phosphor particles and powder of an inorganic material is first prepared and then fired to produce a sintered body containing the phosphor particles.

The same as in the manufacturing method (i) can be applied as the conditions for production of the fired body. Specifically, the maximum temperature during firing of the mixture of phosphor particles and powder of an inorganic material is preferably 1600° C. or lower, more preferably 1400° C. or lower, and particularly preferably 1200° C. or lower. However, during firing of the mixture, the valence of luminescent center ions in the phosphor particles may change, so that the quantum yield of the phosphor particles may decrease. Therefore, during firing of the mixture of phosphor particles and powder of an inorganic material, the firing is preferably performed in a reductive atmosphere or an inert atmosphere. In this way, changes in valence of luminescent center ions can be reduced. The reductive atmosphere is preferably an atmosphere containing hydrogen. The inert atmosphere is preferably a nitrogen atmosphere or an argon atmosphere. Also in the manufacturing method (i), the firing may be performed in a reductive atmosphere or an inert atmosphere.

The average particle diameter (D₅₀) of the inorganic material powder is preferably 3 μm to 50 μm, more preferably 3 μm to 30 μm, and particularly preferably 3 μm to 10 μm. If the particle diameter of the inorganic material powder is too small, a hole cannot sufficiently be formed, which makes it difficult to impregnate a matrix with a transparent material. On the other hand, if the particle diameter of the inorganic material powder is too large, particles are less likely to be melt-bonded, which makes it difficult to form a three-dimensionally continuous skeleton.

Subsequently, when a transparent material is introduced into the sintered body, a hole formed by the skeleton is impregnated with the transparent material. The same as in the manufacturing method (i) can be applied as the method for impregnation. In the wavelength conversion member manufactured by this manufacturing method, the phosphor particles are present inside of the skeleton made of the inorganic material. In this case, the phosphor particles may protrude from the skeleton. In other words, the phosphor particles may adjoin both the skeleton and the hole.

Also in the manufacturing method (ii), like the manufacturing method (i), the sintered body containing the phosphor particles may be impregnated with a mixture of phosphor particles and a transparent material. In doing so, the phosphor particles present in the skeleton may be of the same type as or a different type from the phosphor particles present in the transparent material.

(Wavelength Conversion Element)

FIG. 3 is a schematic cross-sectional view showing a wavelength conversion element according to an embodiment of the present invention. In FIG. 3, the wavelength conversion element 30 includes a wavelength conversion member 10 and a substrate 6 joined to the wavelength conversion member 10. In this embodiment, the wavelength conversion member 10 and the substrate 6 are joined together with a transparent material 4 exposed on a surface of the wavelength conversion member 10 and, in other words, a skeleton made of an inorganic material 3 is joined to the substrate 6 with the same material as the transparent material 4 filled in a hole formed by the skeleton.

Although in this embodiment the wavelength conversion member and the substrate are joined together with the transparent material exposed on a surface of the wavelength conversion member, the method for the joining is not limited to this. The wavelength conversion member and the substrate may be joined together with a transparent material newly applied to the surface of the wavelength conversion member. Furthermore, in doing so, any adhesive material different from the transparent material may be used.

Although in this embodiment the substrate is in a rectangular sheet-like shape and joined to one side of the wavelength conversion member, the substrate is not limited to this shape and may have any shape. For example, the substrate may have a shape covering the side surfaces of the wavelength conversion member.

The substrate is preferably made of an inorganic material and specific examples include glass, ceramics, and metals. Particularly in the case where the wavelength conversion member is used in an application where it reaches high temperatures, ceramic or metal, which have high heat dissipation, is preferably used as the substrate. In the case where the wavelength conversion member is used in a reflective light-emitting device as will be described later, metal is preferably used as the substrate. The ceramic is preferably at least one selected from among aluminum oxide, magnesium oxide, zinc oxide, aluminum nitride, and boron nitride. The metal is preferably at least one selected from among copper, aluminum, and iron.

(Manufacturing Method of Wavelength Conversion Element)

The wavelength conversion element is preferably manufactured by, in producing a wavelength conversion member, bringing a skeleton made of an inorganic material in the wavelength conversion member and a substrate into tight contact with each other before a transparent material hardens and joining the skeleton and the substrate together with the transparent material. Specifically, the wavelength conversion element is preferably manufactured by either one of: a method (i) of impregnating a skeleton made of an inorganic material with a mixture of phosphor particles and a transparent material, bringing a substrate and the skeleton into tight contact with each other before the mixture hardens, and joining the skeleton and the substrate together with the mixture exposed from a hole in the skeleton; and a method (ii) of impregnating a sintered body having a skeleton made of an inorganic material and containing phosphor particles dispersed inside of the skeleton with a transparent material, bringing a substrate and the sintered body into tight contact with each other before the transparent material hardens, and joining the sintered body and the substrate together with the transparent material exposed from a hole in the skeleton. However, the wavelength conversion element may be manufactured by, after the production of a wavelength conversion member, applying a transparent material to a surface of the wavelength conversion member, bringing a skeleton made of an inorganic material in the wavelength conversion member and a substrate into tight contact with each other, and joining the skeleton and the substrate together with the transparent material. Furthermore, in doing so, any adhesive material different from the transparent material may be used.

For example, in a specific example of the manufacturing method (i), when a skeleton made of an inorganic material is immersed into a mixture of phosphor particles and a transparent material to impregnate the skeleton with the mixture and the skeleton is then picked up before the mixture hardens, the mixture can be exposed from a hole in the skeleton. In this case, when the skeleton and a substrate are brought into tight contact with each other in the air, the skeleton and the substrate can be joined together, thus obtaining a wavelength conversion element. Alternatively, the skeleton and the substrate may be brought into tight contact with each other in a state where they are immersed into the mixture, or in other words, the impregnation of the skeleton with the mixture and joining of the skeleton and the substrate may be concurrently performed. The same conditions, including the temperature for impregnation, as in the above-described manufacturing method of the wavelength conversion member can be applied to the conditions in this manufacturing method.

For example, in a specific example of the manufacturing method (ii), when a sintered body of an inorganic material and phosphor particles is immersed into a transparent material to impregnate the sintered body with the transparent material and the sintered body is then picked up before the transparent material hardens, the transparent material can be exposed from a hole in the sintered body. In this case, when the sintered body and a substrate are brought into tight contact with each other in the air, the sintered body and the substrate can be joined together, thus obtaining a wavelength conversion element. Alternatively, the sintered body and the substrate may be brought into tight contact with each other in a state where they are immersed into the transparent material, or in other words, the impregnation of the sintered body with the transparent material and joining of the sintered body and the substrate may be concurrently performed. The same conditions, including the temperature for impregnation, as in the above-described manufacturing method of the wavelength conversion member can be applied to the conditions in this manufacturing method.

As thus far described, in joining a wavelength conversion member and a substrate together in a manufacturing method of a wavelength conversion element, it is preferred to bring the substrate into contact with the skeleton or the sintered body and, in this state, harden the mixture or the transparent material. By doing so, impregnation with the mixture or the transparent material and joining between the skeleton or the sintered body and the substrate can be concurrently performed, so that the manufacturing process for the wavelength conversion element can be shortened.

(Light-Emitting Device)

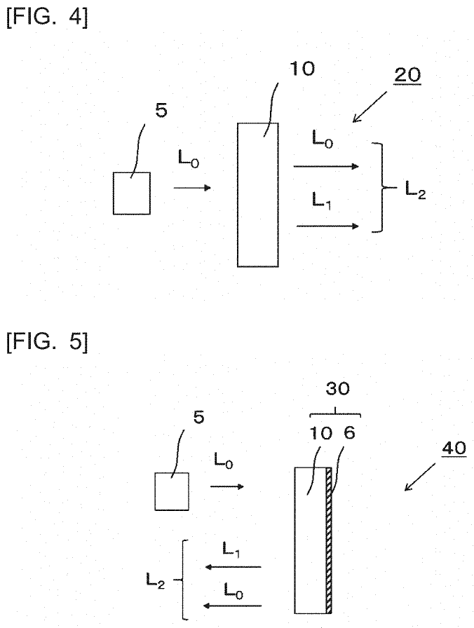

FIG. 4 is a schematic side view showing a light-emitting device in which the wavelength conversion member according to the above-described embodiment of the present invention is used. The light-emitting device according to this embodiment is a light-emitting device in which a transmissive wavelength conversion member is used. As shown in FIG. 4, the light-emitting device 20 includes the wavelength conversion member 10 and a light source 5. Excitation light L₀ emitted from the light source 5 is converted in wavelength to fluorescence L₁ having a longer wavelength than the excitation light L₀ by the wavelength conversion member 10. Furthermore, part of the excitation light L₀ passes through the wavelength conversion member 10. Therefore, the wavelength conversion member 10 emits synthetic light L₂ composed of the excitation light L₀ and the fluorescence L₁. For example, when the excitation light L₀ is a blue light and the fluorescence L₁ is a yellow light, a white synthetic light L₂ can be provided.

FIG. 5 is a schematic side view showing a light-emitting device in which the wavelength conversion element according to the above-described embodiment of the present invention is used. The light-emitting device according to this embodiment is a reflective light-emitting device. As shown in FIG. 5, the light-emitting device 40 includes the wavelength conversion element 30 and a light source 5. Excitation light L₀ emitted from the light source 5 is converted in wavelength to fluorescence L₁ having a longer wavelength than the excitation light L₀ by the wavelength conversion member 10. The fluorescence L₁ and part of the excitation light L₀ are reflected by the substrate 6. Therefore, the wavelength conversion element 30 emits synthetic light L₂ composed of the excitation light L₀ and the fluorescence L₁ from the side of the wavelength conversion element 30 having been irradiated with the excitation light L₀. For example, when the excitation light L₀ is a blue light and the fluorescence L₁ is a yellow light, a white synthetic light L₂ can be provided.

Examples of the light source include an LED and an LD. However, from the perspective of increasing the luminescence intensity of the light-emitting device, an LD, which is capable of emitting high-intensity light, is preferably used as the light source.

### EXAMPLES

Hereinafter, the wavelength conversion member according to the present invention will be described in detail with reference to examples, but the present invention is not limited to the following examples.

Tables 1 to 7 show working examples (Nos. 1 to 12 and 14 to 50) of the present invention and a comparative example (No. 13).

TABLE 1

| | | No. 1 | No. 2 | No. 3 | No. 4 | No. 5 | No. 6 | No. 7 |
|---|---|---|---|---|---|---|---|---|
| Inorganic | Type | MgO | MgO | MgO | MgO | MgO | MgO | MgO |
| Material | Refractive index nd1 | 1.74 | 1.74 | 1.74 | 1.74 | 1.74 | 1.74 | 1.74 |
| | Average particle diameter (μm) | 8 | 8 | 8 | 8 | 8 | 8 | 8 |
| Sintering Aid | Type | — | — | — | — | — | — | — |
| | Average particle diameter (μm) | — | — | — | — | — | — | — |
| Transparent | Type | A | B | C | A | A | A | D |
| Material | Refractive index nd2 | 1.74 | 1.70 | 1.72 | 1.74 | 1.74 | 1.74 | 1.77 |
| | Refractive index difference [nd1 − nd2] | 0.00 | 0.04 | 0.02 | 0.00 | 0.00 | 0.00 | 0.03 |
| Phosphor Powder | Type | YAG | YAG | YAG | YAG | YAG | YAG | YAG |
| Particles | Average particle diameter (μm) | 25 | 25 | 25 | 25 | 25 | 25 | 25 |
| Content of phosphor particles (% by volume) | | 10 | 10 | 10 | 9.5 | 8.5 | 13 | 9.5 |
| [Phosphor particles + Inorganic material]:[Transparent material] | | 75:25 | 75:25 | 75:25 | 79:21 | 87:13 | 58:42 | 79:21 |
| (volume ratio) | | | | | | | | |
| Production of | Thermal treatment temp. (° C.) | 1500 | 1500 | 1500 | 1500 | 1500 | 1500 | 1500 |
| Inorganic Skeleton | Thermal treatment atm. | air | air | air | air | air | air | air |
| Impregnation of | Temperature (° C.) | — | — | — | — | — | — | 820 |
| Transparent Material | | | | | | | | |

| | | | | | | | |
|---|---|---|---|---|---|---|---|
| Thermal diffusivity (×10⁻⁶m²/s) | 2.37 | 2.37 | 2.37 | 2.56 | 3.42 | 2.11 | 2.63 |
| Quantum efficiency (%) | 53 | 53 | 53 | 54 | 52 | 54 | 50 |
| Light permeability | good | good | good | good | good | good | good |

TABLE 2

| | | No. 8 | No. 9 | No. 10 | No. 11 | No. 12 | No. 13 | No. 14 |
|---|---|---|---|---|---|---|---|---|
| Inorganic | Type | MgO | MgO | MgO | MgO | Al₂O₃ | MgO | MgO |
| Material | Refractive index nd1 | 1.74 | 1.74 | 1.74 | 1.74 | 1.77 | 1.74 | 1.74 |
| | Average particle diameter (μm) | 8 | 8 | 8 | 8 | 8 | 8 | 8 |
| Sintering Aid | Type | — | — | — | — | — | — | — |
| | Average particle diameter (μm) | — | — | — | — | — | — | — |
| Transparent | Type | E | A | A | C | C | — | A |
| Material | Refractive index nd2 | 1.75 | 1.74 | 1.74 | 1.72 | 1.72 | — | 1.74 |
| | Refractave index difference [nd1 − nd2] | 0.01 | 0.00 | 0.00 | 0.02 | 0.05 | — | 0.00 |
| Phosphor Powder | Type | YAG | YAG | YAG | YAG | YAG | YAG | YAG |
| Particles | Average particle diameter (μm) | 25 | 25 | 25 | 25 | 25 | 25 | 25 |
| Content of phosphor particles (% by volume) | | 10 | 10 | 10 | 10 | 10.5 | 10 | 75 |
| [Phosphor particles + Inorganic material]:[Transparent material] | | 75:25 | 75:25 | 75:25 | 75:25 | 71:29 | 75:25 | 75:25 |
| (volume ratio) | | | | | | | | |
| Production of | Thermal treatment temp. (° C.) | 1500 | 1500 | 1500 | 1000 | 1000 | 1500 | 1500 |
| Inorganic Skeleton | Thermal treatment atm. | air | inert | reductive | air | air | air | air |
| Impregnation of | Temperature (° C.) | 480 | — | — | — | — | — | — |
| Transparent Material | | | | | | | | |

| | | | | | | | |
|---|---|---|---|---|---|---|---|
| Thermal diffusivity (×10⁻⁶m²/s) | 2.42 | 2.31 | 2.33 | 1.92 | 1.35 | — | 1.23 |
| Quantum efficiency (%) | 51 | 63 | 69 | 63 | 62 | 57 | 52 |
| Light permeability | good | good | good | good | good | poor | fair |

TABLE 3

| | | No. 15 | No. 16 | No. 17 | No. 18 | No. 19 | No. 20 | No. 21 |
|---|---|---|---|---|---|---|---|---|
| Inorganic | Type | MgO | MgO | MgO | MgO | MgO | MgO | MgO |
| Material | Refractive index nd1 | 1.74 | 1.74 | 1.74 | 1.74 | 1.74 | 1.74 | 1.74 |
| | Average particle diameter (μm) | 8 | 8 | 8 | 8 | 8 | 8 | 8 |
| Sintering Aid | Type | — | — | — | — | — | — | — |
| | Average particle diameter (μm) | — | — | — | — | — | — | — |
| Transparent | Type | B | A | A | A | A | A | B |
| Material | Refractive index nd2 | 1.70 | 1.74 | 1.74 | 1.74 | 1.74 | 1.74 | 1.70 |
| | Refractive index difference [nd1 − nd2] | 0.04 | 0.00 | 0.00 | 0.00 | 0.00 | 0.00 | 0.04 |
| Phosphor Powder | Type | YAG | YAG | YAG | YAG | YAG | YAG | YAG |
| Particles | Average particle diameter (μm) | 25 | 25 | 25 | 25 | 25 | 25 | 25 |
| Content of phosphor particles (% by volume) | | 55 | 45 | 25 | 15 | 5 | 75 | 55 |
| [Phosphor particles + Inorganic material]:[Transparent material] | | 75:25 | 75:25 | 75:25 | 75:25 | 75:25 | 75:25 | 75:25 |
| (volume ratio) | | | | | | | | |
| Production of | Thermal treatment temp. (° C.) | 1500 | 1500 | 1500 | 1500 | 1500 | 1500 | 1500 |
| Inorganic Skeleton | Thermal treatment atm. | air | air | air | air | air | reductive | reductive |
| Impregnation of | Temperature (° C.) | — | — | — | — | — | — | — |
| Transparent Material | | | | | | | | |

| | | | | | | | |
|---|---|---|---|---|---|---|---|
| Thermal diffusivity (×10⁻⁶m²/s) | 1.36 | 1.55 | 2.13 | 2.30 | 2.48 | 1.25 | 1.34 |
| Quantum efficiency (%) | 52 | 52 | 52 | 53 | 54 | 69 | 68 |
| Light permeability | fair | fair | good | good | good | fair | fair |

TABLE 4

| | | No. 22 | No. 23 | No. 24 | No. 25 | No. 26 | No. 27 | No. 28 |
|---|---|---|---|---|---|---|---|---|
| Inorganic | Type | MgO | MgO | MgO | MgO | MgO | MgO | MgO |
| Material | Refractive index nd1 | 1.74 | 1.74 | 1.74 | 1.74 | 1.74 | 1.74 | 1.74 |
| | Average particle diameter (μm) | 8 | 8 | 8 | 8 | 8 | 8 | 8 |
| Sintering Aid | Type | — | — | — | — | — | — | — |
| | Average particle diameter (μm) | — | — | — | — | — | — | — |
| Transparent | Type | A | A | A | A | A | F | G |
| Material | Refractive index nd2 | 1.74 | 1.74 | 1.74 | 1.74 | 1.74 | 1.63 | 1.58 |
| | Refractive index difference [nd1 − nd2] | 0.00 | 0.00 | 0.00 | 0.00 | 0.00 | 0.11 | 0.16 |
| Phosphor Powder | Type | YAG | YAG | YAG | YAG | YAG | YAG | YAG |
| Particles | Average particle diameter (μm) | 25 | 25 | 25 | 25 | 25 | 25 | 25 |
| Content of phosphor particles (% by volume) | | 45 | 25 | 15 | 5 | 10 | 10 | 10 |
| [Phosphor particles + Inorganic material]:[Transparent material] | | 75:25 | 75:25 | 75:25 | 75:25 | 75:25 | 75:25 | 75:25 |
| (volume ratio) | | | | | | | | |
| Production of | Thermal treatment temp. (° C.) | 1500 | 1500 | 1500 | 1500 | 1700 | 1500 | 1500 |
| Inorganic Skeleton | Thermal treatment atm. | reductive | reductive | reductive | reductive | air | air | air |
| Impregnation of | Temperature (° C.) | — | — | — | — | — | — | — |
| Transparent Material | | | | | | | | |

| | | | | | | | |
|---|---|---|---|---|---|---|---|
| Thermal diffusivity (×10⁻⁶m²/s) | 1.56 | 2.15 | 2.29 | 2.46 | 3.42 | 2.37 | 2.37 |
| Quantum efficiency (%) | 67 | 68 | 67 | 68 | 23 | 53 | 53 |
| Light permeability | fair | good | good | good | good | fair | fair |

TABLE 5

| | | No. 29 | No. 30 | No. 31 | No. 32 | No. 33 | No. 34 | No. 35 |
|---|---|---|---|---|---|---|---|---|
| Inorganic | Type | MgO | MgO | MgO | MgO | Me | MgO | MgO |
| Material | Refractive index nd1 | 1.74 | 1.74 | 1.74 | 1.74 | 1.74 | 1.74 | 1.74 |
| | Average particle diameter (μm) | 8 | 8 | 8 | 8 | 8 | 8 | 8 |
| Sintering Aid | Type | — | — | — | — | — | — | — |
| | Average particle diameter (μm) | — | — | — | — | — | — | — |
| Transparent | Type | H | G | G | G | G | G | G |
| Material | Refractive index nd2 | 1.46 | 1.58 | 1.58 | 1.58 | 1.58 | 1.58 | 1.58 |
| | Refractive index difference [nd1 − nd2] | 0.28 | 0.16 | 0.16 | 0.16 | 0.16 | 0.16 | 0.16 |
| Phosphor Powder | Type | YAG | YAG | YAG | YAG | YAG | YAG | YAG |
| Particles | Average particle diameter (μm) | 25 | 25 | 25 | 25 | 25 | 25 | 25 |
| Content of phosphor particles (% by volume) | | 10 | 55 | 45 | 25 | 15 | 5 | 45 |
| [Phosphor particles + Inorganic material]:[Transparent material] | | 75:25 | 75:25 | 75:25 | 75:25 | 75:25 | 75:25 | 75:25 |
| (volume ratio) | | | | | | | | |
| Production of | Thermal treatment temp. (° C.) | 1500 | 1500 | 1500 | 1500 | 1500 | 1500 | 1500 |
| Inorganic Skeleton | Thermal treatment atm. | air | air | air | air | air | air | reductive |
| Impregnation of | Temperature (° C.) | 900 | — | — | — | — | — | — |
| Transparent Material | | | | | | | | |

| | | | | | | | |
|---|---|---|---|---|---|---|---|
| Thermal diffusivity (×10⁻⁶m²/s) | 2.37 | 1.36 | 1.55 | 2.13 | 2.30 | 2.48 | 1.56 |
| Quantum efficiency (%) | 50 | 52 | 52 | 52 | 53 | 54 | 67 |
| Light permeability | fair | fair | fair | fair | fair | fair | fair |

TABLE 6

| | | No. 36 | No. 37 | No. 38 | No. 39 | No. 40 | No. 41 | No. 42 |
|---|---|---|---|---|---|---|---|---|
| Inorganic | Type | MgO | MgO | MgO | MgO | MgO | MgO | MgO |
| Material | Refractive index nd1 | 1.74 | 1.74 | 1.74 | 1.74 | 1.74 | 1.74 | 1.74 |
| | Average particle diameter (μm) | 8 | 8 | 8 | 8 | 8 | 8 | 8 |
| Sintering Aid | Type | — | — | — | MgF₂ | MgF₂ | MgF₂ | MgF₂ |
| | Average particle diameter (μm) | — | — | — | 5 | 5 | 5 | 5 |
| Transparent | Type | G | G | G | A | G | A | G |
| Material | Refractive index nd2 | 1.58 | 1.58 | 1.58 | 1.74 | 1.58 | 1.74 | 1.58 |
| | Refractive index difference [nd1 − nd2] | 0.16 | 0.16 | 0.16 | 0.00 | 0.16 | 0.00 | 0.16 |
| Phosphor Powder | Type | YAG | YAG | YAG | YAG | YAG | YAG | YAG |
| Particles | Average particle diameter (μm) | 25 | 25 | 25 | 25 | 25 | 25 | 25 |
| Content of phosphor particles (% by volume) | | 25 | 15 | 5 | 10 | 10 | 10 | 10 |
| [Phosphor particles + Inorganic material]:[Transparent material] | | 75:25 | 75:25 | 75:25 | 75:25 | 75:25 | 75:25 | 75:25 |
| (volume ratio) | | | | | | | | |
| Production of | Thermal treatment temp. (° C.) | 1500 | 1500 | 1500 | 1000 | 1000 | 1000 | 1000 |
| Inorganic Skeleton | Thermal treatment atm. | reductive | reductive | reductive | air | air | inert | inert |
| Impregnation of | Temperature (° C.) | — | — | — | — | — | — | — |
| Transparent Material | | | | | | | | |

| | | | | | | | |
|---|---|---|---|---|---|---|---|
| Thermal diffusivity (×10⁻⁶m²/s) | 2.15 | 2.29 | 2.46 | 2.13 | 2.12 | 2.14 | 2.13 |
| Quantum efficiency (%) | 68 | 67 | 68 | 63 | 63 | 83 | 82 |
| Light permeability | fair | fair | fair | good | fair | good | fair |

TABLE 7

| | | No. 43 | No. 44 | No. 45 | No. 46 | No. 47 | No. 48 | No. 49 | No. 50 |
|---|---|---|---|---|---|---|---|---|---|
| Inorganic | Type | MgO | MgO | MgO | MgO | MgO | MgO | MgO | MgO |
| Material | Refractive index nd1 | 1.74 | 1.74 | 1.74 | 1.74 | 1.74 | 1.74 | 1.74 | 1.74 |
| | Average particle diameter (μm) | 8 | 8 | 8 | 8 | 8 | 8 | 8 | 8 |
| Sintering Aid | Type | CaF₂ | CaF₂ | CaF₂ | CaF₂ | MgF₂ | MgF₂ | MgF₂ | MgF₂ |
| | Average particle diameter (μm) | 3 | 3 | 3 | 3 | 0.007 | 0.007 | 0.007 | 0.007 |
| Transparent | Type | A | G | A | G | A | G | A | G |
| Material | Refractive index nd2 | 1.74 | 1.58 | 1.74 | 1.58 | 1.74 | 1.58 | 1.74 | 1.58 |
| | Refractive index difference [nd1 − nd2] | 0.00 | 0.16 | 0.00 | 0.16 | 0.00 | 0.16 | 0.00 | 0.16 |
| Phosphor Powder | Type | YAG | YAG | YAG | YAG | YAG | YAG | YAG | YAG |
| Particles | Average particle diameter (μm) | 25 | 25 | 25 | 25 | 25 | 25 | 25 | 25 |
| Content of phosphor particles (% by volume) | | 10 | 10 | 10 | 10 | 10 | 10 | 10 | 10 |
| [Phosphor particles + Inorganic material]:[Transparent material] | | 75:25 | 75:25 | 75:25 | 75:25 | 75:25 | 75:25 | 75:25 | 75:25 |
| (volume ratio) | | | | | | | | | |
| Production of | Thermal treatment temp. (° C.) | 1000 | 1000 | 1000 | 1000 | 1000 | 1000 | 1000 | 1000 |
| Inorganic Skeleton | Thermal treatment atm. | air | air | inert | inert | air | air | inert | inert |
| Impregnation of | Temperature (° C.) | — | — | — | — | — | — | — | — |
| Transparent Material | | | | | | | | | |

| | | | | | | | | |
|---|---|---|---|---|---|---|---|---|
| Thermal diffusivity (×10⁻⁶m²/s) | 1.89 | 1.90 | 1.91 | 1.90 | 2.42 | 2.40 | 2.43 | 2.42 |
| Quantum efficiency (%) | 61 | 60 | 78 | 77 | 64 | 63 | 82 | 83 |
| Light permeability | good | fair | good | fair | good | fair | good | fair |

Each of Working Examples (Nos. 1 to 12 and 14 to 50) was produced in the following manner. First, phosphor particles and an inorganic material were mixed to give their contents shown in Tables 1 to 7, thus obtaining a mixture. The materials below were used in the working examples. In Tables 1 to 7, the content of phosphor particles indicates a percentage by volume of the phosphor particles in the mixture of the phosphor particles and the inorganic material. Furthermore, the ratio between the total content of phosphor particles and inorganic material and the content of transparent material for immersion ([Phosphor particles+Inorganic material]: [Transparent material]), and the ratio between the total content of phosphor particles, inorganic material, and sintering aid and the content of transparent material for impregnation ([Phosphor particles+Inorganic material+Sintering aid]: [Transparent material]) were determined by binarizing the cross-sectional view of the obtained wavelength conversion member and calculating the respective proportions of the regions of the above materials in the total cross-sectional area.

(a) Inorganic Material

MgO powder (thermal conductivity: approximately 42 W/m·K, average particle diameter D₅₀: 8 μm, refractive index (nd): 1.74)

Al₂O₃ powder (thermal conductivity: approximately 20 W/m·K, average particle diameter D₅₀: 10 μm, refractive index (nd): 1.77)

(a′) Sintering Aid

MgF₂ powder (average particle diameter: 5 μm)

CaF₂ powder (average particle diameter: 3 μm)

MgF₂ nanopowder (average particle diameter: 0.007 μm)

(b) Phosphor Particles

YAG phosphor particles (Y₃Al₅O₁₂, average particle diameter: 25 μm)

The above-described obtained mixture was put into a mold and pressed at a pressure of 0.45 MPa in the mold, thus producing a preform. The obtained preform was heated to a predetermined temperature in an atmosphere shown in Tables 1 to 7, held at the temperature for four hours, and then gradually cooled to ordinary temperature, thus producing a sintered body having a skeleton made of the inorganic material and containing the phosphor particles dispersed inside of the skeleton. In the case where the above thermal treatment (firing) was performed in an atmosphere containing hydrogen, the thermal treatment atmosphere was defined as a reductive atmosphere. In the case where the above thermal treatment (firing) was performed in a nitrogen atmosphere, the thermal treatment atmosphere was defined as an inert atmosphere.

The above sintered body was impregnated with a below-described transparent material at a temperature shown in Tables 1 to 7.

(c) Transparent Material

Transparent material A (thiourethane-based resin, refractive index (nd): 1.74)

Transparent material B (vinyl-based resin, refractive index (nd): 1.70)

Transparent material C (acrylic resin, refractive index (nd): 1.72)

Transparent material D (bismuth phosphate glass, refractive index (nd): 1.77)

Transparent material E (tin phosphate glass, refractive index (nd): 1.75)

Transparent material F (sulfide-based resin, refractive index (nd): 1.63)

Transparent material G (silicone resin (glass resin manufactured by Techneglas Inc.), refractive index (nd): 1.58)

Transparent material H (borosilicate glass, refractive index (nd): 1.46)

Among the above transparent materials, each resin was impregnated into the sintered body at ordinary temperature. The thiourethane-based resin and the vinyl-based resin were used in a state of a mixture of a liquid resin as a main liquid and a liquid hardener. Each resin was cured by thermal treatment and then subjected to grinding and polishing processing, thus obtaining a rectangular sheet-like wavelength conversion member.

Among the above transparent materials, each glass was melted by heating to a temperature shown in Tables 1 to 7 and then impregnated into the sintered body. After the hardening of the glass, the glass was subjected to grinding and polishing processing, thus obtaining a rectangular sheet-like wavelength conversion member.

A sample was produced in the same manner as in Working Example No. 1 except that no transparent material was impregnated into the sintered body, and this sample was employed as Comparative Example No. 13. This comparative example was a sintered body having a skeleton made of an inorganic material and containing phosphor particles dispersed inside of the skeleton, but was free from transparent material in the skeleton.

The obtained wavelength conversion members were evaluated in terms of thermal diffusivity, quantum efficiency, and light permeability in the following manners. The results are shown in Tables 1 to 7. Furthermore, a photograph of a partial cross section of the wavelength conversion member of Working Example 1 is shown in FIG. 2.

The thermal diffusivity was measured with a thermal diffusivity measurement system ai-phase manufactured by ai-Phase Co., Ltd. The measurement of the thermal diffusivity for each sample was made eleven times in total within a temperature range of 105° C.±5° C. and the value obtained by averaging the eleven measurement results was employed as the thermal diffusivity of the sample.

The quantum efficiency indicates a value calculated by the following equation and was measured with an absolute PL quantum yield spectrometer (manufactured by Hamamatsu Photonics K.K.).

Quantum efficiency=[(the number of photons emitted as fluorescence from a sample)/(the number of photons absorbed by the sample)]×100(%)

The light permeability was determined, with the obtained wavelength conversion member placed on a paper with characters under a 1000-lux fluorescent lamp, by whether or not the shadows of the characters could be visually recognized. The thickness of the wavelength conversion member was 500 μm. The wavelength conversion members where the character shadows could be visually recognized were determined to be “good”, whereas the wavelength conversion member where the character shadows could not be visually recognized even at a thickness of 200 μm was determined to be “poor”. Furthermore, the wavelength conversion members where the character shadows could not be visually recognized at a thickness of 500 μm but could be visually recognized at a thickness of 200 μm was determined to be “fair”.

As is obvious from Tables 1 to 7, the wavelength conversion members of the working examples (Nos. 1 to 12 and 14 to 50) exhibited high thermal diffusivities of 1.23×10⁻⁶ m²/s or more. Furthermore, all of the working examples exhibited fine light permeability. Particularly, the working examples having a small content of phosphor particles exhibited a tendency to increase the thermal diffusivity and the light permeability. The working examples where firing was performed in an inert or reductive atmosphere and the working examples where the firing temperature was low exhibited a tendency to increase the quantum efficiency. In contrast, the wavelength conversion member of the comparative example (No. 13) exhibited poor light permeability because it had a large difference in refractive index (nd) between the skeleton and the air contained in the hole and therefore exhibited excessively large light scattering at the interface between the skeleton and the air. Furthermore, the wavelength conversion member of No. 13 had a large volume of hole and therefore could not be measured in terms of thermal diffusivity.

### REFERENCE SIGNS LIST

1 matrix
2 phosphor particle
3 inorganic material
4 transparent material
5 light source
6 substrate
10 wavelength conversion member
20 light-emitting device
30 wavelength conversion element
40 light-emitting device

1. A wavelength conversion member containing a matrix and phosphor particles dispersed in the matrix,
the matrix comprising:
a skeleton made of an inorganic material; and
a transparent material filled in a hole formed by the skeleton,
the inorganic material having a higher thermal conductivity than the transparent material.

2. The wavelength conversion member according to claim 1, wherein the skeleton is formed of a sintered body.

3. The wavelength conversion member according to claim 1, wherein the phosphor particles are dispersed in the hole.

4. The wavelength conversion member according to claim 1, wherein the phosphor particles are dispersed inside of the skeleton.

5. The wavelength conversion member according to claim 1, wherein the phosphor particles adjoin both the skeleton and the hole.

6. The wavelength conversion member according to claim 1, wherein a volume proportion of the transparent material in the entire wavelength conversion member is 10 to 80%.

7. The wavelength conversion member according to claim 1, wherein a difference in refractive index between the inorganic material and the transparent material is 0.3 or less.

8. The wavelength conversion member according to claim 1, wherein the skeleton is formed by three-dimensional continuation of powder of the inorganic material.

9. The wavelength conversion member according to claim 1, wherein the hole is substantially free from discreteness.

10. The wavelength conversion member according to claim 1, wherein the inorganic material contains at least one selected from among aluminum oxide, magnesium oxide, zinc oxide, aluminum nitride, and boron nitride.

11. The wavelength conversion member according to claim 1, wherein the inorganic material is glass.

12. The wavelength conversion member according to claim 1, wherein the inorganic material is resin.

13. The wavelength conversion member according to claim 1, having a thickness of 1000 μm or less.

14. The wavelength conversion member according to claim 1, having a thermal diffusivity of 1×10⁻⁶ m²/s or more.

15. The wavelength conversion member according to claim 1, having a quantum efficiency of 20% or more.

16. A method for manufacturing the wavelength conversion member according to claims 1 to 15, the method comprising the steps of:
firing powder of an inorganic material to make a skeleton made of the inorganic material;
preparing a mixture of phosphor particles and a transparent material; and
impregnating a hole formed by the skeleton with the mixture.

17. The method for manufacturing the wavelength conversion member according to claim 16, wherein a maximum temperature during the firing of the powder of the inorganic material is 1600° C. or lower.

18. The method for manufacturing the wavelength conversion member according to claim 16 or 17, wherein a maximum temperature during the impregnation of the mixture of the phosphor particles and the transparent material into the skeleton is 1000° C. or lower.

19. A method for manufacturing the wavelength conversion member according to claim 1, the method comprising the steps of:
preparing a mixture of phosphor particles and powder of an inorganic material;
firing the mixture to produce a sintered body having a skeleton made of the inorganic material and containing the phosphor particles dispersed inside of the skeleton; and
impregnating a hole formed by the skeleton with a transparent material.

20. The method for manufacturing the wavelength conversion member according to claim 19, wherein a maximum temperature during the firing of the mixture of the phosphor particles and the powder of the inorganic material is 1600° C. or lower.

21. The method for manufacturing the wavelength conversion member according to claim 19, wherein a maximum temperature during the impregnation of the transparent material into the skeleton is 1000° C. or lower.

22. The method for manufacturing the wavelength conversion member according to claim 14, wherein the powder of the inorganic material has an average particle diameter of 3 μm or more.

23. A wavelength conversion element comprising: the wavelength conversion member according to claim 1; and a substrate joined to the wavelength conversion member.

24. The wavelength conversion element according to claim 23, wherein the substrate is joined to the wavelength conversion member with the transparent material exposed on a surface of the wavelength conversion member.

25. A method for manufacturing the wavelength conversion element according to claim 23, the method comprising the steps of:
firing powder of an inorganic material to make a skeleton made of the inorganic material;
preparing a mixture of phosphor particles and a transparent material;
impregnating a hole formed by the skeleton with the mixture; and
bringing a substrate and the skeleton into tight contact with each other before the mixture hardens and joining the skeleton and the substrate together with the mixture exposed from the hole.

26. A method for manufacturing the wavelength conversion element according to claim 23, the method comprising the steps of:
preparing a mixture of phosphor particles and powder of an inorganic material;
firing the mixture to produce a sintered body having a skeleton made of the inorganic material and containing the phosphor particles dispersed inside of the skeleton;
impregnating a hole formed by the skeleton with a transparent material; and
bringing a substrate and the sintered body before the transparent material hardens and joining the sintered body and the substrate together with the transparent material exposed from the hole.

27. A light-emitting device comprising: the wavelength conversion member according to claim 1; and a light source operable to irradiate the wavelength conversion member with excitation light.

28. A light-emitting device comprising: the wavelength conversion element according to claim 23; and a light source operable to irradiate the wavelength conversion element with excitation light.

29. The light-emitting device according to claim 27, wherein the light source is a laser diode.
